(19) United States
(12) Patent Application Publication
(10) Pub. No.: US 2002/0186016 A1
(43) Pub. Date: Dec. 12, 2002

(54) Electrification quantity measurement apparatus, electrification quantity measurement method, static electricity discharge detection apparatus, and static electricity discharge detection method

(76) Inventor: Noriyuki Kodama, Tokyo (JP)

Correspondence Address: KATTEN MUCHIN ZAVIS ROSENMAN, 575 MADISON AVENUE, NEW YORK, NY, 10022-2585, US

(21) Appl. No.: 10/162,336

(22) Filed: Jun. 4, 2002

(30) Foreign Application Priority Data
Jun. 6, 2001 (JP) 2001-171752

(51) Int. Cl. G01R 29/12

(52) U.S. Cl. 324/457

(57) ABSTRACT

In an electrification quantity measurement apparatus including a probe for coming in contact with a measurement subject, a first resistor connected at a first terminal thereof to the probe, and a capacitor connected between a second terminal of the first resistor and ground, there is provided an offset current cancel means for canceling an offset current of the capacitor generated by an ionizer in order to measure an electrification quantity of the measurement subject placed in an ionizer environment.

### BACKGROUND OF THE INVENTION

The present invention relates to an electrification quantity measurement apparatus, its measurement method, a static electricity discharge detection apparatus, and its detection method. In particular, the present invention relates to an electrification quantity measurement apparatus, its measurement method, a static electricity discharge detection apparatus, and its detection method suitable for semiconductor apparatuses, hard disk drive apparatuses, and manufacturing apparatuses, jigs and tools for these apparatuses.

Until a semiconductor device is completed, various processing processes are applied. In a wafer diffusion process, electrification phenomena are caused by exposure of a wafer to plasma in the plasma etching process and the plasma ashing process for removing photoresists. Besides, the surface of an insulation film is sometimes electrified with charge in the UV cleaning process for applying UV light and cleaning organic substances that have stuck on the semiconductor wafer and the ion implantation process as well. The charge electrified on the surface of an insulation film not only becomes easy to adsorb particles in the environment, but also causes degradation of characteristics of the semiconductor device. Therefore, there is a demand for monitoring the electrified charge quantity.

In the inspection process, a conveyance apparatus called handler is used. In an IC test apparatus, a large number of devices to be tested housed in a tray are conveyed into a handler. Each device to be tested is brought into electrical contact with a test head, and an IC test apparatus conducts a test. When the test is finished, each device to be tested is expelled from the test head and placed on a tray depending on a test result. Assortment into categories, such as standardized articles and non-standardized articles, is thus conducted.

ESD (Electro-static Discharge) faults in the IC handler attract attention in recent years. For example, they are reported in “MINIMIZING ESD HAZARD IN IC TEST HANDLERS AND AUTOMATIC TRIM/FORM MACHINE,” 1993 EOS/ESD Symposium, p. 57, as well in detail.

One of problems concerning the electrification in the handler is contact electrification. This is caused by the following reason. When substances come in contact with each other, charge exchange is caused between their surfaces. When the two substances separate from each other, the generated charge separates rapidly from the contact surface in the case in which the substance is metal. In the case of insulation substance, the charge does not easily move and hence remains in that place and the potential becomes very high. This results in the contact electrification. In the concrete, when holding and conveying the device, an insulate package of the device and a conductive adsorption head for conveyance come in contact, and electrification is caused.

Another problem concerning the electrification in the handler is inductive electrification from a charged body located near the device. To be concrete, charge that is opposite in polarity to the electrified charge appears on a conductor surface located near the charged package surface. Charge that is the same in polarity as the electrified charge appears on a conductor surface of the opposite side (this is called induction phenomenon). In this state, if the conductor is grounded, then charge (called superfluous conductive charge) that is the same in polarity as the electrified charge attempts to separate from the region having the electrified charge as far as possible and escapes to the ground through a pin. This is called discharge caused by induction type device electrification model. In discharge of this device electrification model, the duration time of the discharge current is approximately 1 nanosecond and extremely short as compared with the diffusion constant of thermal diffusion. The peak current quantity amounts to several A (Ampere) in some cases. Before the heat diffuses from a heat generation place and the temperature becomes low, therefore, the portion is thermally destroyed in some cases. Furthermore, in some cases, a very high voltage is applied to a gate oxide film and a gate insulation film is destroyed.

In order to inspect electric performances among performances of a semiconductor device serving as a product, a socket for connecting the semiconductor device to a test board is used to attach and detach a large number of semiconductor devices repetitively. Therefore, a large amount of charge is stored by contact electrification. When a semiconductor device is inserted into the socket, the internal conductor of the device is subjected to induction electrification by the charge. When a metal portion of the socket comes in contact with a pin of the device, static electricity discharge in the device electrification model occurs and the device is destroyed.

When conveying and handling devices, the adsorption nozzle is necessarily in contact with a package as heretofore described. Accordingly it is difficult to avoid the contact electrification. If moisture adheres to the substance surface, electrification becomes hard to occur because the resistance of the surface becomes lower and it becomes for the charge to be emitted into the atmosphere as well. However, the LSI package is a very good insulator, and the IC handler handles the LSI package at high temperature and low humidity in some cases. Therefore, in such a situation, electrification on the package surface readily occurs, i.e., destruction due to static electricity discharge readily occurs.

In the IC handler, therefore, an apparatus called ionizer neutralizes the charge. The ionizer ionizes the air to positive and negative ions. The ionizer blows the positive and negative ions against the charged substance at the same time or at short periods. If the substance is charged positively in advance, negative ions are taken in. If the substance is charged negatively in advance, positive ions are taken in. The potential can be thus lowered. Ideally, it is desirable that the positive ions are equal in quantity to the negative ions. As a matter of fact, balance of ion collapses in some cases, and charge removal is not conducted efficiently enough in some cases.

Furthermore, it takes several seconds for the ionizer to remove the charge from the charged substance. In the handler, however, the conveyance speed of the device is at most one second. It is not certain whether the charge has been removed surely. Therefore, there is a demand for measuring the quantity of charge induced by the charge on the package, or more preferably monitoring it during the conveyance.

When conducting electric measurement of a semiconductor device, a pusher closes the insertion face of the socket, when ion wind is blown toward the semiconductor device-measuring socket from its periphery. (The pusher is a main body, which drives an adsorption nozzle. An air cylinder is used in its movement mechanism.) Therefore, ion wind, which should be blown against the vicinity of the semiconductor device, does not drive against the insertion face of the socket a large portion of time. Accordingly, static electricity cannot be removed efficiently. Therefore, there is a demand for measuring and monitoring the electrification quantity of the socket.

Abrupt charge is a problem. As for portions with which LSI pins might come in contact, such as a tray and a shuttle, a film of high resistance is provided or plated thereon in some cases.

Even if countermeasures against electrification and discharge are taken, they are not perfect and the possibility that a change with the passage of time, such as film degradation or exfoliation, is very high. Therefore, it is wanted to conduct monitoring to determine whether there is not exfoliation of a high-resistance film not only at the time of initial conveyance adjustment but also at all times.

As a device for finding these static electricity discharge locations, there is known a system using a discharge time difference as announced by Lin D. L. et al. in “Robust ESD Event Locator System with Event Characterization”, Electrical Overstress/Electrostatic Discharge Symposium, 1997 Proceedings, pp. 88-98A. In this system, there is a drawback in expense that an expensive oscilloscope must be used for measuring an electromagnetic wave time difference measurement, additionally, this system has various technical problems. For example, an electromagnetic bulb of a working apparatus and other electromagnetic wave generation sources cause noise and hamper the certainty of finding. Furthermore, if the conveyance apparatus shades an antenna and a discharge location, it becomes difficult to determine the discharge source location.

Conventionally, potential is used to represent an electrification situation of semiconductor devices and its management criterion. For representing an electrification phenomenon by using a voltage, however, its capacitance value (device capacitance or capacitance to the grounds) must be made clear. This point is described in, for example, “CDM ESD Test Considered Phenomena of Division and Reduction of High Voltage in the Environment,” 1996 EOS/ESD SIMPOSIUM, p. 54. As described therein, a quantity Q of charge charged in the semiconductor device, an applied voltage V, and capacitance C satisfy the relation Q=CV, i.e., V=Q/C. If the device conveyance state or the surrounding state changes, therefore, the capacitance changes. Accordingly, attention should be paid to the fact that the potential also changes in response thereto. In other words, in the case where a breakdown voltage is used, it cannot be that an accurate criterion value is displayed as the management criterion of electrification, unless the relation to the device capacitance is indicated. As regards this point, a test method of calculating the charge quantity and determining a breakdown quantity is shown in Japanese Unexamined Patent Publication (KOKAI) No. 9-218241. An example using it in an assembly process of a print circuit board is shown in Japanese Unexamined Patent Publication (KOKAI) No. 2000-81468.

This point is indicated more clearly in “Static electricity discharge measurement for frontier devices and prevention countermeasure,” 10th RCJ symposium record. That is, it has been proposed to find a relation between the device capacitance and the breakdown charge quantity in a CDM (Charged Device Model) test and to measure the device capacitance in a breakdown risk state and make the breakdown charge at that time a line management criterion value. There has been also proposed therein a method of conducting line management by using a minimum breakdown charge quantity as a criterion in the case in which the device capacitance cannot be measured or it changes.

In general, a non-contact surface potential meter is used to conduct potential measurement. However, the surface potential meter has a problem that the potential of a pin, i.e., the potential of an internal conductor cannot be measured because devices pins are very minute. Furthermore, when measuring the potential of the package surface of the semiconductor device, it is possible to know only the potential of the package surface represented by taking V as the unit. Furthermore, there is a problem that a potential appears when a measurement subject is apart from the ground, but a potential does appear when the measurement subject is near the ground.

Therefore, it is shown in Japanese Unexamined Patent Publication (KOKAI) No. 11-6850 and Japanese Patent No. 2908240 that a method of measuring the charge quantity is effective. To be concrete, it is a measuring apparatus for calculating the charge quantity from the relation Q=CV by connecting a capacitor having capacitance (its capacitance C is, for example, 1000 pF) larger than the device capacitance (which is approximately 10 pF in general) to a devices as shown in FIG. 12, transferring superfluous conductive charge in the device to the capacitor, and measuring a potential (V) of the capacitor.

In this system, positive and negative ions exist when conducting measurement by using an ionizer. However, the positive and negative ions do not balance perfectly. Because of the apparatus configuration, the capacitor incorporated in the apparatus is charged immediately by a current caused by ion wind. Accordingly, the conventional charge quantity measurement apparatus cannot be used.

Putting together the foregoing description, the conventional system has the following problems.

(1) The conventional charge quantity measurement apparatus has a problem that it cannot conduct measurement in the ionizer environment.

(2) Apparatuses for measuring the electrification quantity in the conveyance apparatus for conveying a silicon wafer or a package are limited to only surface potential meters. Conditions under which the apparatus can be used are very limited.

(3) There are no measurement apparatuses for determining a place where static electricity discharge is occurring, measuring the electrification quantity, and conducting measurement to determine whether the countermeasure against electrification is good, especially in such a state that the conveyance apparatus is conducting typical conveyance.

FIG. 13 is a diagram showing inductive electrification caused by static charge on the package surface of a semiconductor device. FIGS. 14A to 14D are diagrams showing a device electrification model, and its test apparatus and test results. FIG. 15 is a diagram showing the measurement principal of superfluous conductive charge.

### SUMMARY OF THE INVENTION

An object of the present invention is to improve the drawbacks of the conventional technique, and in particular, to provide (1) an electrification charge measurement apparatus and a measurement method capable of measuring the electrification quantity in the ionizer environment with high precision, (2) an electrification charge measurement apparatus and a measurement method for measuring an electrification quantity of a conveyance subject on a conveyance apparatus for conveying a silicon wafer and a package, (3) an electrification charge measurement apparatus and a measurement method for measuring an electrification quantity and determining whether a countermeasure against electrification is good in a typical conveyance apparatus, and (4) an electrification charge measurement apparatus and a measurement method for determining a place where static electricity discharge is occurring.

In order to achieve the object of the present invention, basically a technical configuration hereafter described is adopted.

The first aspect of the present invention is an electrification quantity measurement apparatus comprising: a measurement subject placed in an ionizer environment; a probe for coming in contact with the measurement subject; a first resistor connected at a first terminal thereof to the probe; a capacitor connected between a second terminal of the first resistor and ground; and offset current cancel means for canceling an offset current of the capacitor generated by an ionizer in order to measure an electrification quantity of the measurement subject.

In the second aspect of the present invention, the offset current cancel means comprising: a voltage source a second resistor for applying an output voltage of the voltage source to a connection node between the first resistor and the capacitor, the second resistor being sufficiently higher in resistance than the first resistor; and control means for controlling an output voltage of the voltage source in response to a terminal voltage of the capacitor.

In the third aspect of the present invention, the offset current cancel means comprising: a current source; and control means for controlling an output current of the current source in response to a terminal voltage of the capacitor.

In the fourth aspect of the present invention, the apparatus further comprising: a third resistor connected between terminals of the capacitor so as to discharge charge within the capacitor; and recording means for acquiring a discharge current that flows through the third resistor or a discharge voltage of the capacitor.

In the fifth aspect of the present invention, the apparatus further comprising: a third resistor connected between terminals of the capacitor so as to discharge charge within the capacitor; and measurement means for measuring a peak value of a discharge current that flows through the third resistor or a peak value of a discharge voltage of the capacitor.

In the sixth aspect of the present invention, the apparatus further comprising: a third resistor connected between terminals of the capacitor so as to discharge charge within the capacitor; and an integration circuit for integrating a discharge current that flows through the third resistor.

The seventh aspect of the present invention is an electrification quantity measurement apparatus comprising: a measurement subject a probe for coming in contact with the measurement subject a first resistor connected at a first terminal thereof to the probe a capacitor connected between a second terminal of the first resistor and ground a second resistor connected between terminals of the capacitor so as to discharge charge within the capacitor; and recording means for acquiring a curve of a discharge current that flows through the second resistor.

The eighth aspect of the present invention is an electrification quantity measurement apparatus comprising: a measurement subject a probe for coming in contact with the measurement subject a first resistor connected at a first terminal thereof to the probe a capacitor connected between a second terminal of the first resistor and ground a second resistor connected between terminals of the capacitor so as to discharge charge within the capacitor; and measurement means for measuring a peak value of a discharge current that flows through the second resistor.

The ninth aspect of the present invention is an electrification quantity measurement apparatus comprising: a measurement subject a probe for coming in contact with the measurement subject a first resistor connected at a first terminal thereof to the probe a capacitor connected between a second terminal of the first resistor and ground a second resistor connected between terminals of the capacitor so as to discharge charge within the capacitor; and an integration circuit for integrating a discharge current that flows through the second resistor.

The tenth aspect of the present invention is an electrification quantity measurement apparatus comprising: a measurement subject a resistor connected between the measurement subject and ground; and recording means for recording a current waveform that flows through the resistor.

The eleventh aspect of the present invention is an electrification quantity measurement apparatus comprising: a measurement subject a resistor connected between the measurement subject and ground; and measurement means for measuring a peak value of a discharge current that flows through the resistor.

The twelfth aspect of the present invention is an electrification quantity measurement apparatus comprising: a measurement subject a first resistor connected at a first terminal thereof to the measurement subject a capacitor connected between a second terminal of the first resistor and ground a second resistor connected between terminals of the capacitor so as to discharge charge within the capacitor; and recording means for acquiring a curve of a discharge current that flows through the second resistor.

The thirteenth aspect of the present invention is an electrification quantity measurement apparatus comprising: a measurement subject a first resistor connected at a first terminal thereof to the measurement subject a capacitor connected between a second terminal of the first resistor and ground a second resistor connected between terminals of the capacitor so as to discharge charge within the capacitor; and measurement means for measuring a peak value of a discharge current that flows through the second resistor.

The fourteenth aspect of the present invention is an electrification quantity measurement apparatus comprising: a measurement subject a first resistor connected at a first terminal thereof to the measurement subject a capacitor connected between a second terminal of the first resistor and ground a second resistor connected between terminals of the capacitor so as to discharge charge within the capacitor; and an integration circuit for integrating a discharge current that flows through the second resistor.

In the fifteenth aspect of the present invention, the measurement subject is a semiconductor fabrication apparatus such as a stage, a shuttle, a wafer conveyance arm, and an adsorption arm of a handler.

The sixteenth aspect of the present invention is a static electricity discharge detection apparatus comprising: a tray and/or shuttle for conveying a part a resistor connected between the tray and/or shuttle and frame ground; and recording means for recording a waveform of a discharge current that flows through the resistor.

The seventeenth aspect of the present invention is a static electricity discharge detection apparatus comprising: a tray and/or shuttle for conveying a part a resistor connected between the tray and/or shuttle and frame ground; and measurement means for measuring a peak value of a discharge current that flows through the resistor and time taken until the peak is reached.

### BRIEF DESCRIPTION OF THE DRAWINGS

FIG. 1 is a diagram showing a configuration of an electrification quantity measurement apparatus in accordance with a first example of the present invention;

FIG. 2 is a diagram showing a potential measurement method of the first example;

FIGS. 3A and 3B are circuit diagrams showing a configuration of a second example in accordance with the present invention;

FIGS. 4A and 4B are graphs showing measured terminal voltages of a capacitor in the second example at the time of charging and discharging, respectively;

FIGS. 5A, 5B, 5C and 5D are a diagram and a graph showing a third example of the present invention, respectively;

FIGS. 6A and 6B are diagrams showing a configuration of a fourth example of the present invention;

FIG. 7 is a graph showing an example of a measurement result of the fourth example;

FIGS. 8A and 8B are drawings showing a configuration of a fifth example of the present invention;

FIGS. 9A and 9B are drawings showing a sixth example of the present invention;

FIGS. 10A and 10B are drawings showing the sixth example of the present invention;

FIGS. 11A and 11B are graphs illustrating the sixth example of the present invention;

FIG. 12 is a drawing showing a seventh example of the present example;

FIG. 13 is a drawing showing a conventional art;

FIGS. 14A to 14D are drawings showing a conventional art; and

FIG. 15 is a drawing showing a conventional art.

### DESCRIPTION OF THE PREFERRED EMBODIMENTS

In the present invention, charge quantities of an electrified semiconductor device, hard disk drive apparatus, and jigs and tools used in the fabrication process of these apparatuses are measured. Embodiments of the present invention include the following example (A) to (H):

(A) an electrification quantity measurement apparatus with an offset current cancel mechanism in an ionizer environment added thereto, and its measuring method;

(B) an electrification quantity measurement apparatus with a high resistor having such a resistance value as to leak an offset current in an ionizer environment added thereto, and its measuring method;

(C) an electrification quantity measurement apparatus for calculating a charge quantity by delaying a discharge current from a measuring subject, lowering a frequency band, and measuring and integrating the discharge current and its measuring method;

(D) an electrification quantity measurement apparatus for applying the schemes of (A) to (C) to a stage in a handler and a conveyance shuttle, and its measuring method;

(E) an electrification quantity measurement apparatus for applying the scheme of (C) to an adsorption nozzle in the handler, and its measuring method;

(F) an electrification quantity measurement apparatus for applying the schemes of (D) and (E) to electrification quantity of socket of the test board within a handler or electrification quantity of the LSI caused by the electrification of the socket, and its measuring method;

(G) an electrification quantity measurement apparatus for applying the schemes of (A) and (B) to an arm, which handles a wafer, and a carrier box (FOUP), and its measuring method; and

(H) an electrification quantity measurement apparatus for applying the schemes of (A) to (C) to an arm, which handles fabrication (assembly) parts such as a semiconductor wafer, and a carrier box (FOUP) which stores semiconductor wafers, and its measuring method.

Hereafter, examples of an electrification quantity measuring apparatus and its measuring method in accordance with the present invention will be described in detail by referring to drawings.

(First Embodiment)

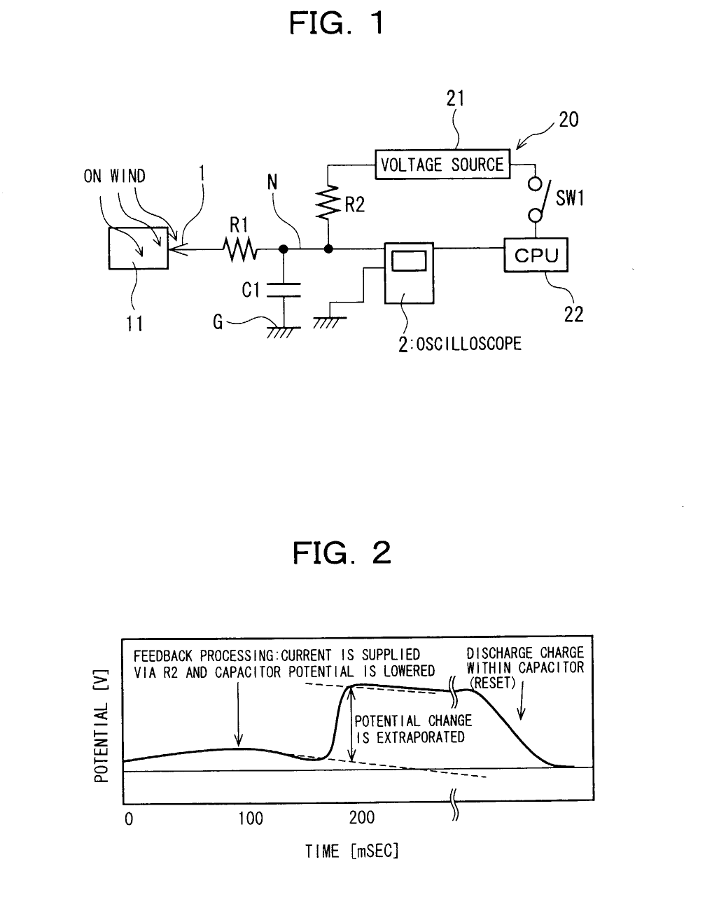

FIGS. 1 and 2 are drawings showing a first example of an electrification quantity measurement apparatus and its measurement method of the present invention.

In FIGS. 1 and 2, there is shown an electrification quantity measurement apparatus including: a probe 1 for coming in contact with a measurement subject 11; a first resistor R1 connected at a first terminal thereof to the probe 1; a capacitor C1 connected between a second terminal of the first resistor R1 and ground; and offset current cancel means 20 for canceling an offset current of the capacitor C1 generated by an ionizer in order to measure an electrification quantity of the measurement subject 11 placed in an ionizer environment.

The offset current cancel means includes: a voltage source 21 for canceling the offset current of the capacitor; a second resistor R2 for applying an output voltage of the voltage source 21 to a connection node N between the first resistor R1 and the capacitor C1, the second resistor R2 being sufficiently higher in resistance than the first resistor R1; and control means 22 for controlling an output voltage of the voltage source 21 in response to a terminal voltage of the capacitor C1.

In FIG. 1, the reference numeral 2 designates an oscilloscope to record the change of terminal voltage of the capacitor C1.

Hereafter, the first example will be described in more detail.

As shown in FIG. 1, a probe pin 1 is connected to a first end of a capacitor C1 having capacitance of 1000 pF via a resistor R1 (10 kΩ). A second end of the capacitor C1 is connected to the ground. The first end of the capacitor C1 is connected to an operational amplifier (not illustrated) for voltage measurement, and the voltage of the capacitor C1 is measured.

An output voltage of a voltage source 21 is applied to the first end of the capacitor C1 via a resistor R2 having high resistance of approximately 10 GΩ in order to be able to supply a current to the capacitor C1. The time constant of charging is 1 second. In an ionizer environment, ion wind is blown against the probe pin 1. Accordingly, a current continually flows into the capacitor C1 via the probe pin 1 and the resistor R1. In order to cancel this current, a CPU 22 exercises control so as to change the potential of a voltage source 21.

The ion wind is comparatively stable. However, there is a variation in accordance with the location of the probe tip and turbulence of the ion wind. This variation has a band of approximately one second in time. High frequency components are not included in the variation.

At the time of measurement, the probe 1 is brought into contact with a measurement subject 11. Although the time constant of charging of the capacitor C1 at that time depends upon the resistance of the measurement subject 11, it becomes approximately 1 microsecond. Therefore, the CPU 22 continually reads an output value of the operational amplifier at periods of approximately 0.1 microsecond, and changes the potential of the voltage source 21 at periods of approximately several hundreds milliseconds.

If there is a potential change having a rising edge of approximately 1 microsecond, the CPU 22 stops feedback control and acquires and preserves a charging waveform.

The charge stored across the capacitor C1 may be discharged by a switch such as a TRIAC as in the conventional scheme. Or a current may be supplied from the voltage for feedback to make the potential equal to 0.

A measurement method will now be described.

A semiconductor device (measurement subject) 11 having capacitance (referred to as device capacitance) of approximately 0.5 pF is placed in an ionizer environment.

Before the measurement start, ion balance (difference in quantity between positive ions and negative ions) becomes approximately 20 V. In this state, the measurement probe 1 is brought close to the measurement subject 11. Immediately before the contact, a switch SW1 for canceling a current generated by an influence of ion wind is pressed. And the probe 1 is brought into contact with the measurement subject 11, and the discharge waveform is preserved.

The discharge waveform is superposition of a waveform obtained until the probe 1 is brought into contact with the measurement subject 11 and the capacitor C1 is charged, a current after the charging, and an influence of a leak current caused by the capacitor C1 and the measuring operational amplifier. Within a time range in which the influence of them does not exist, therefore, the measured voltage becomes constant. On the basis thereof, therefore, the charge quantity is calculated.

Furthermore, if feedback is exercised and the voltage gradually changes, or if the potential is gradually changed by a leak current of the capacitor or the like, then the potential is extrapolated and the potential of the capacitor is found from a difference thereof as shown in FIG. 2.

Most charge of the measurement subject 11 charges the capacitor C1. Therefore, the charge quantity can be derived from the relation Q=CV.

In the case of an ionizer of AC discharge type, positive and negative ions are blown alternately at a frequency of the main power supply. In some cases, therefore, there is a variation of this frequency component. In this case, (1) circuit constants may be set so as to exercise feedback in the period, or (2) since the influence thereof appears in the charging waveform of the capacitor C1, data processing may be conducted by handling it as offset of a constant current.

(Second Embodiment)

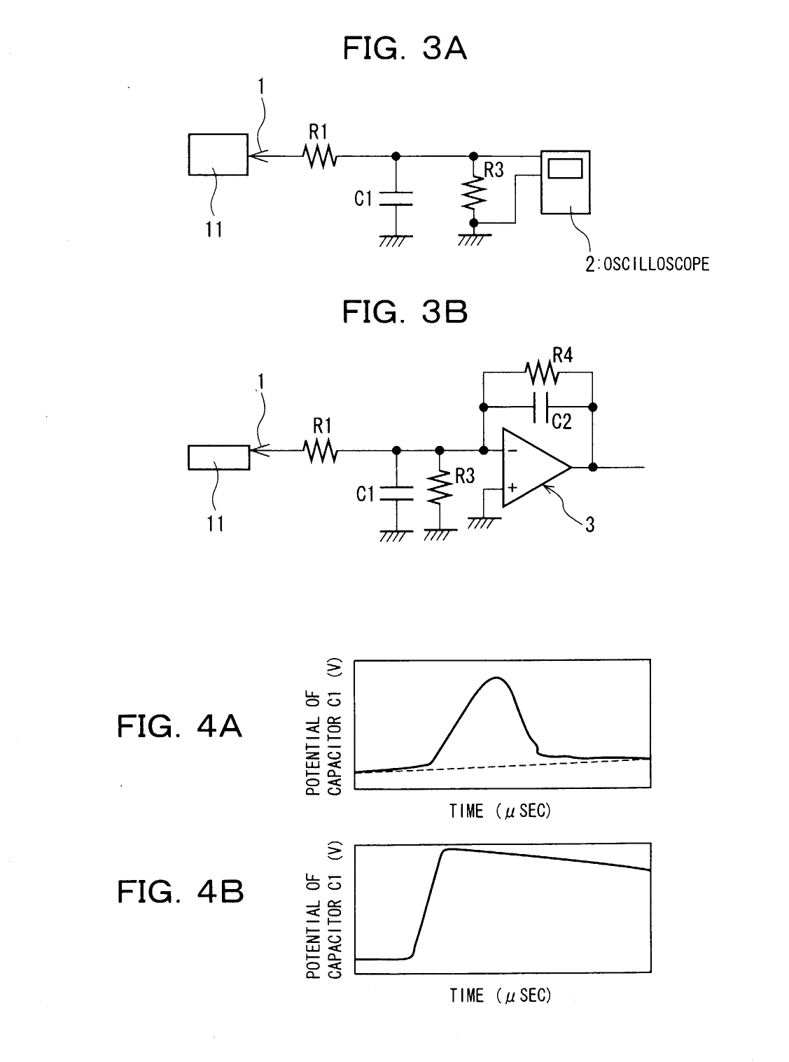

FIGS. 3A, 3B, 4A and 4B are drawings showing a second example of the present invention. FIG. 4A is a graph showing the terminal voltage of the capacitor at the time of charging. FIG. 4B is a graph showing the terminal voltage of the capacitor at the time of discharging.

In FIG. 3A, there is shown an electrification quantity measurement apparatus including: a probe 1 for coming in contact with a measurement subject 11; a first resistor R1 connected at a first terminal thereof to the probe 1; a capacitor C1 connected between a second terminal of the first resistor R1 and the ground; a second resistor R3 connected between terminals of the capacitor C1 to discharge charge within the capacitor C1; and recording means 2 such as an oscilloscope for acquiring potential of the resistor R3 (capacitor C1).

In FIG. 3B, there is shown an electrification quantity measurement apparatus including: a second resistor R3 connected between terminals of the capacitor C1 to discharge charge within the capacitor C1; and an integration circuit 3 for integrating a discharge current that flows through the second resistor R3.

Hereafter, the second example will be described in more detail.

As shown in FIG. 3A, there is provided a resistor R3 for discharging the electric charge that is charged within the capacitor C1. Since the probe comes in contact with the measurement subject, the capacitor C1 is charged with the electric charge and the electric charge flows out to the resistor R3. Respective resistance values are set so that time constants of charging and discharging will become approximately 1 microsecond and 100 milliseconds, respectively, and an offset current caused by the ionizer will not be stored across the capacitor. A voltage waveform of the capacitance C1 (resistance R3) is acquired (FIGS. 4A and 4B). On the basis of the peak value of this waveform, the charge quantity is calculated from the relation Q=CV. In other words, by finding the potential of the capacitor at time far earlier than the time when discharge has started, the charge quantity can be measured.

As for the potential measurement of the capacitor, a peak holding circuit for holding the peak of the voltage waveform may be used. The resistor R1 is provided to prevent a LSI from being destroyed by an abrupt current change in the case in which the measurement subject is the LSI.

Furthermore, as shown in FIG. 3B, the charge quantity may be measured by integrating the discharge current with an integrator. In this case, the gain of the integrator in the range of DC to a low frequency is limited.

Furthermore, in a circuit configuration similar to that of FIG. 3A, an ammeter may be inserted between the resistor R3 and the capacitor C1, instead of the apparatus for recording the voltage waveform. In that case, the capacitance of the capacitor and the resistance are arbitrary, but they are determined to assume such values as to make the current waveform dull enough to make the ammeter respond. As for the charge quantity, the base current is subtracted when integrating the discharge current and calculating the charge quantity (FIG. 4B).

(Third Embodiment)

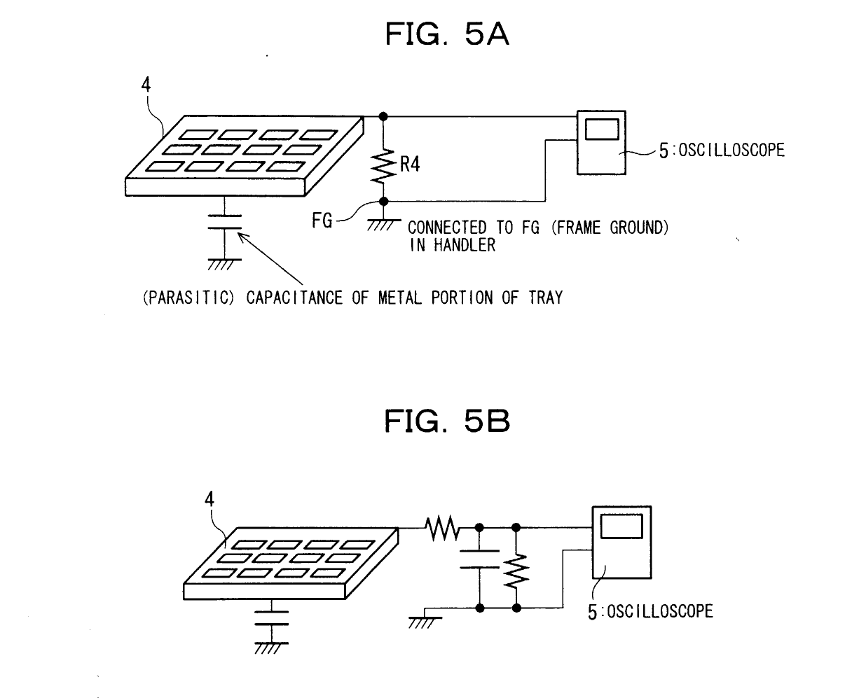

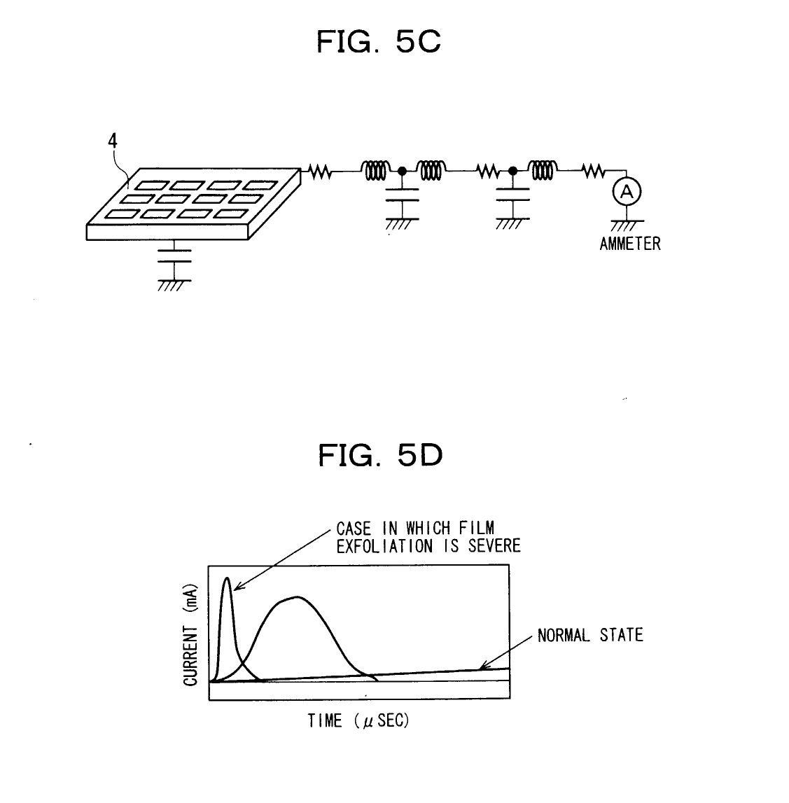

FIGS. 5A, 5B, 5C and 5D are diagrams showing a third example of the present invention. In FIG. 5A, there is shown a film exfoliation monitor apparatus including a tray and shuttle 4 for conveying a semiconductor IC, the tray and shuttle 4 coated with a high-resistance film on the surface thereof; a resistor R4 connected between the tray and shuttle 4 and frame ground G; and recording means 5 for recording a waveform of a discharge current that flows through the resistor R4.

Hereafter, the third example will be described in more detail.

Surfaces of the tray and shuttle are covered with a high-resistance film. An arm for conveyance (not illustrated), an air cylinder for moving an IC in an up-and-down direction, and an adsorption head for vacuum absorbing are attached to the conveyance apparatus. An adsorption nozzle is attached to a portion that comes in direct contact with an IC package.

When the adsorption nozzle has released the IC over the tray, the semiconductor device falls and is received by the tray. If the term of use becomes long, there is a change with the passage of time such as exfoliation of the high-resistance film. In the third example, the film exfoliation is always monitored.

As for the apparatus configuration, the shuttle and tray 4 is insulated from the ground, and connected to frame ground FG only via a resistor R4 as shown in FIG. 5A. In the third example, the film exfoliation is monitored by monitoring a current that flows through the resistor R4. In this case, the current measurement may be conducted by using a filter that removes frequencies lower than the frequency band of ordinary discharge currents. A measuring instrument 5 is set so as to come in a measurable frequency.

Even if a device pin comes in contact with a metal portion of the tray in the film exfoliation monitor apparatus for tray and shuttle having such a configuration, charge usually flows to the frame ground (FG) with a time constant of at least several tens to several hundreds millisecond and is removed because of existence of the high-resistance film. If the high-resistance film has become thin, however, the resistance is low and the peak of the waveform appears early. The point that weighs are not an integral value of the discharge current, but is its peak value. The earlier the peak value appears, the more serious the film exfoliation is. By monitoring the time when the peak is reached, therefore, the film exfoliation can be monitored (FIG. 5B).

A scheme for measuring a potential waveform instead of the current waveform may be used as in the scheme such as the second example.

As shown in FIGS. 5B and 5C, the low pass filter (LPF) is provided between a tray and/or a shuttle 4 and the oscilloscope 5. In general, a handler uses motors to drive shuttles or pushers therein, and the motor often causes noises such as 40 Hz switching noise or 50 Hz noise by the commercial frequency or the like. For this reason LPFs as shown in FIGS. 5B or 5C, a high pass filter (HPF) or a band pass filter (BPF) not shown in drawings are used to reduce above-mentioned noises and obtain accurate data without an influence by noises.

(Fourth Embodiment)

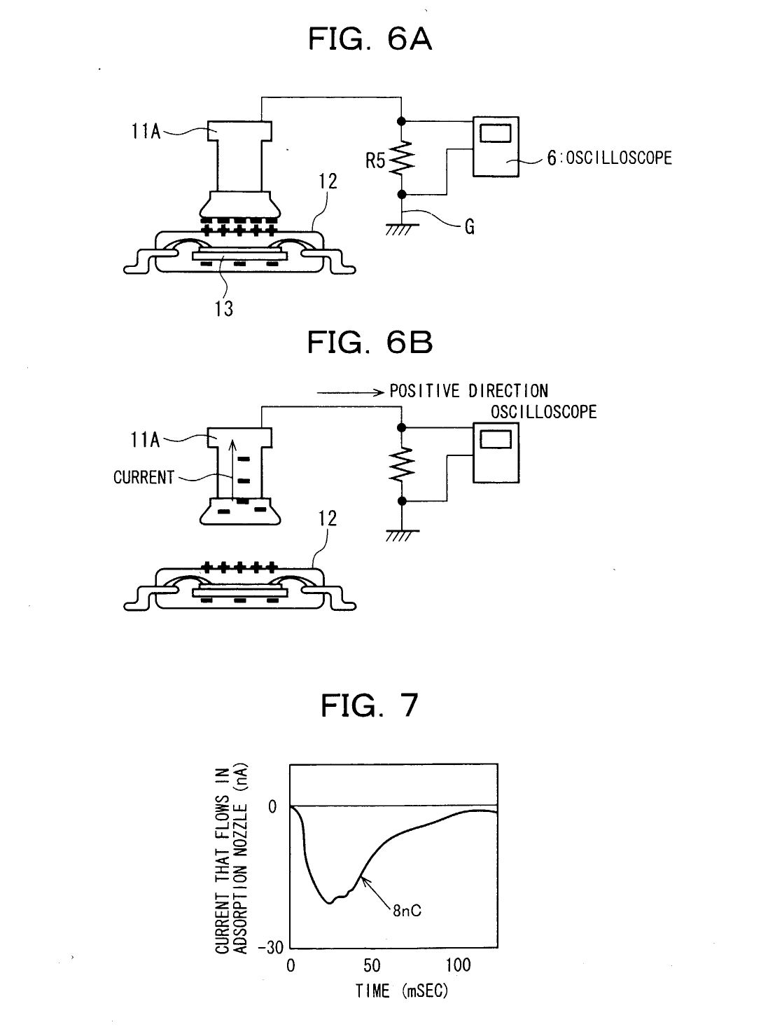

FIGS. 6A, 6B and 7 are diagrams showing a fourth example of the present invention. In FIGS. 6A and 6B, there is shown an electrification quantity measurement apparatus including a resistor R5 connected between a measurement subject 11A and the ground G, and recording means 6 for recording a waveform of a current that flows through the resistor R5.

Hereafter, the fourth example will be described in more detail.

When conveying a LSI package (hereafter referred to as package) in a handler, contact electrification occurs between an adsorption nozzle 11A that grasps the package and a package 12. The fourth example is a measurement apparatus to monitor above-mentioned exfoliation electrification quantity.

When grasping the package 12 in the handler, the conductive adsorption nozzle 11A is used. At the time of exfoliation of them, however, charge is separated, and charge remains on the surface of the insulate package 11A and the insulate package 11A is electrified. This charge induces charge on a LSI 13 in the package 12. When a pin of the LSI 13 comes in contact with a conductive stage or the like, charge having the same polarity as the induced charge is discharged, and consequently the LSI is destroyed. This is called F-CDM destruction model. The electrification quantity is monitored at the time of conveyance, and destruction of the LSI is predicted. If the electrification quantity becomes large, an alarm is issued.

This example has a configuration shown in FIG. 6. So as to be capable of measuring a current absorbed by an adsorption head 11A having a conductive adsorption nozzle attached thereto, the adsorption head is insulated from an air cylinder to which the adsorption head is attached (not illustrated).

Besides the above described configuration, the configuration in which a capacitor is charged with charge as shown in FIG. 1 may also be adopted. The configuration in which a current measurement is conducted after a sufficient delay as shown in FIGS. 3A and 3B may also be used.

If the package 12 is charged positively in the electrification quantity measurement apparatus having such a configuration, then negative charge flows into the adsorption nozzle as shown in FIG. 7. The time constant of the flowing in is approximately 10 msec at 1E6 ohm/mm² although it depends on the resistance of the nozzle. Actually, the adsorption face does not separate from the package surface at the same time. Therefore, the absorption current assumes a little wider distribution. The electrification charge quantity becomes its integral value. To be accurate, if charge exists in the package, then a component of an induction current from the charge is also contained.

(Fifth Embodiment)

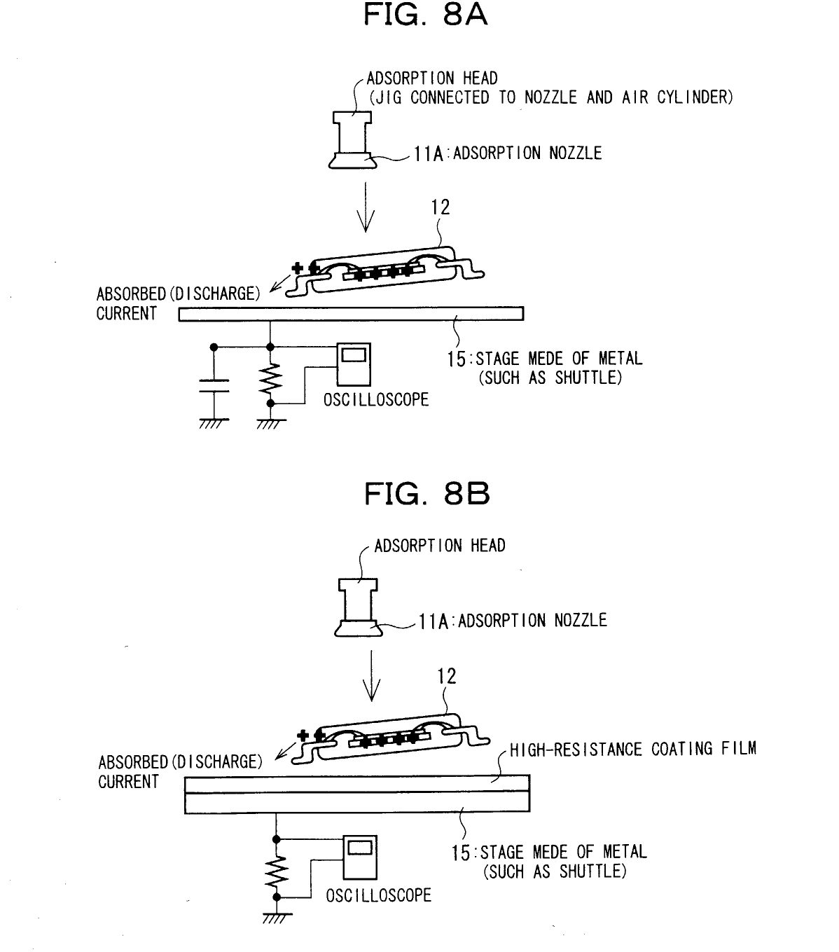

FIGS. 8A and 8B are drawings showing a fifth example of the present invention.

On the basis of a current absorbed in a shuttle 15 that conveys a package 12 in a handler, the charge quantity is measured by using the configuration of FIGS. 3A and 3B. In the case of a metal stage, the current is delayed sufficiently and measured (FIG. 8A). In the case of a shuttle coated with a high-resistance film, a scheme in which the absorbed current is measured as it is may be adopted (FIG. 8B).

(Sixth Embodiment)

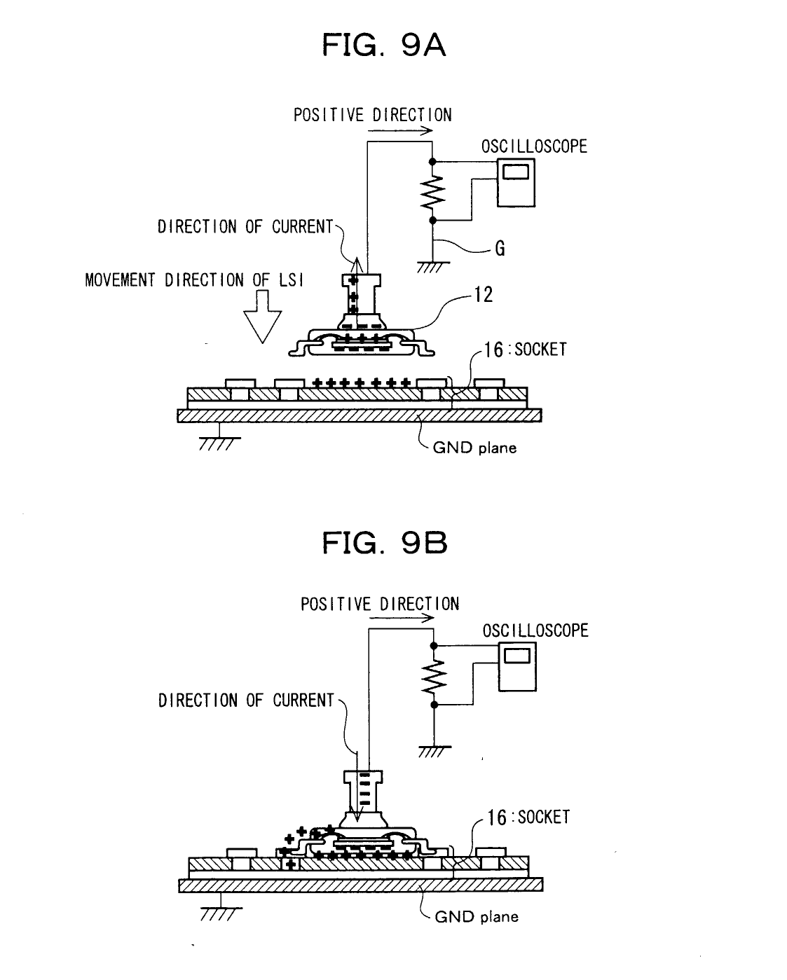

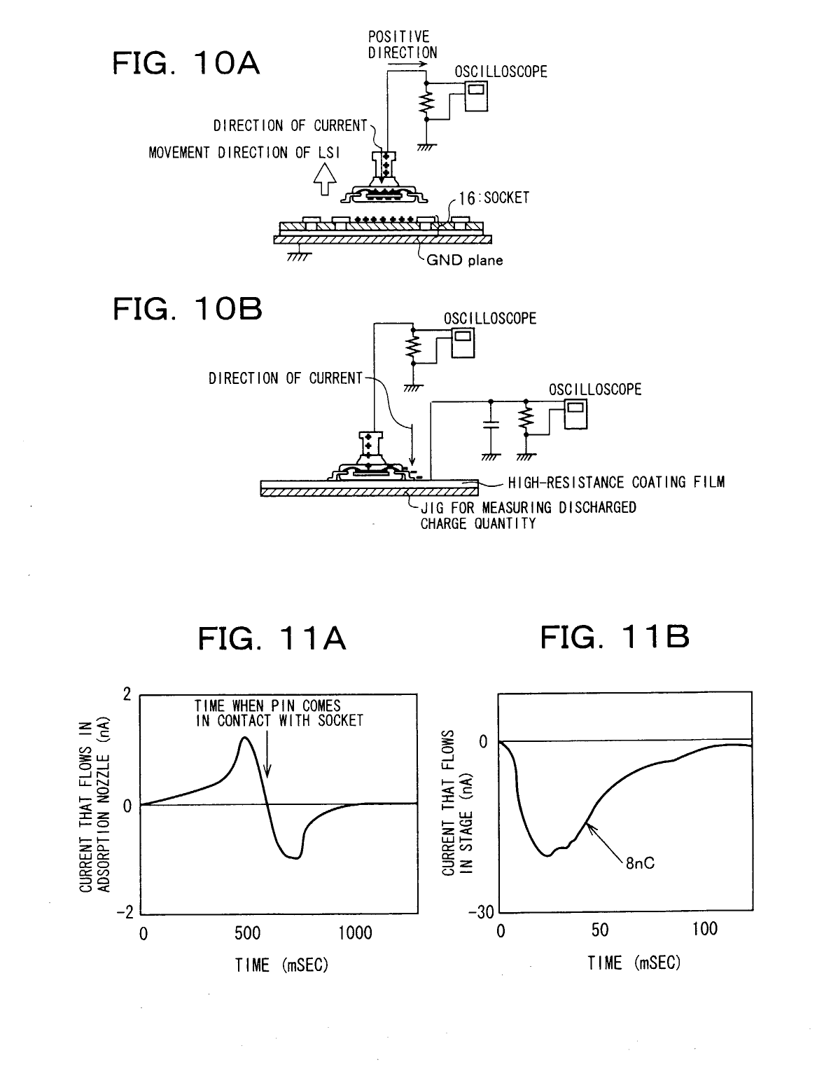

FIGS. 9A, 9B, 10A, 10B, 11A and 11B show a sixth example of the present invention. FIGS. 9A, 9B, 10A, and 10B are drawings showing a method of induction electrification of an LSI caused by electrification of a socket of a test board.

If an LSI approaches when an insulation portion of a socket 16 is charged positively, then an island portion provided within a package 12 is charged negatively by induction electrification, and at the same time an opposite island portion is charged positively. On a surface of an adsorption nozzle 11A (opposed to the package 12), negative charge is induced. The charge quantity is determined by capacitance division.

As the LSI approaches, the quantity of negative charge induced on the surface of the nozzle 11A increases, and positive charge flows from the nozzle to the ground side (FIG. 9A). The moment a pin of the LSI has come in contact with a conductive pin of a socket 16, positive charge induced in the internal conductor flows out, and negative charge on the surface of the nozzle drawn by the positive charge is released, resulting in a current (FIG. 9B). If the LSI leaves the socket in such a state that negative charge is superfluous within the LSI, then capacitance on the socket surface and within the LSI becomes dominant, and positive charge is induced by the negative charge to gather on the socket surface, resulting in a current (FIG. 10A). The LSI is brought into contact with a jig or tool for charge measurement. A discharge current is measured, and a superfluous conductive charge quantity within the LSI is measured (FIG. 10B).

Previously in the CDM test, relations among the device capacitance, destruction voltage, and destruction charge quantity are known. On the basis of the charge quantity, therefore, the risk of destruction of the LSI can be judged. Or the risk of destruction of the LSI can be judged on the basis of the absorption current of the nozzle and the charge quantity that has flown to the nozzle. Furthermore, the risk of destruction of the LSI can be judged on the basis of absorption current quantity when the destruction has occurred until then, the change of the absorption current, and the charge quantity (integral value).

FIG. 11A is a graph of a measurement example of a current that flows into the adsorption nozzle. FIG. 11B is a graph of a measurement example of a current that flows into the stage.

(Seventh Embodiment)

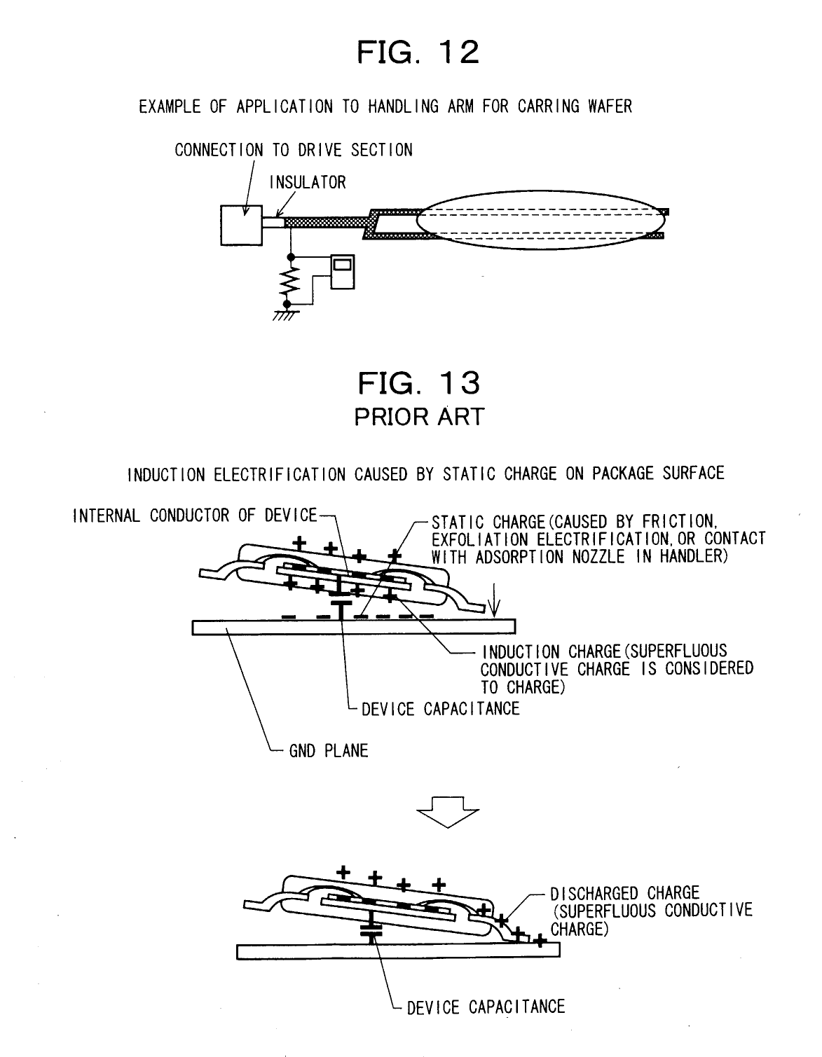

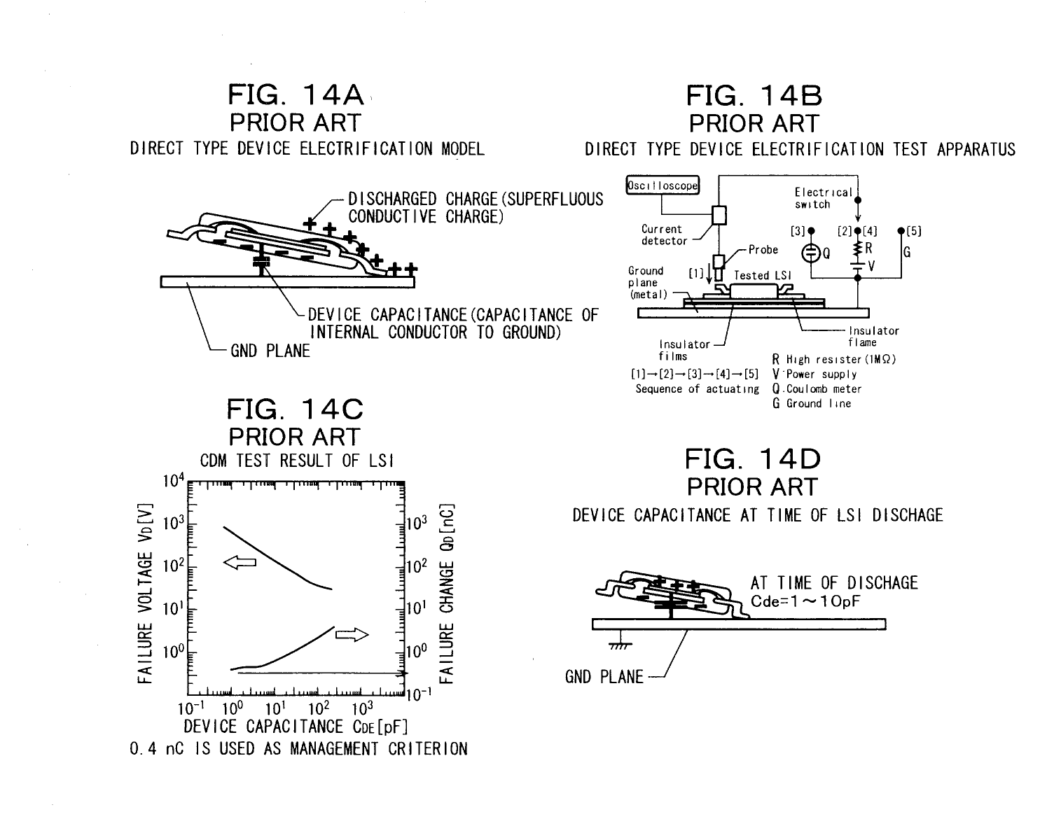

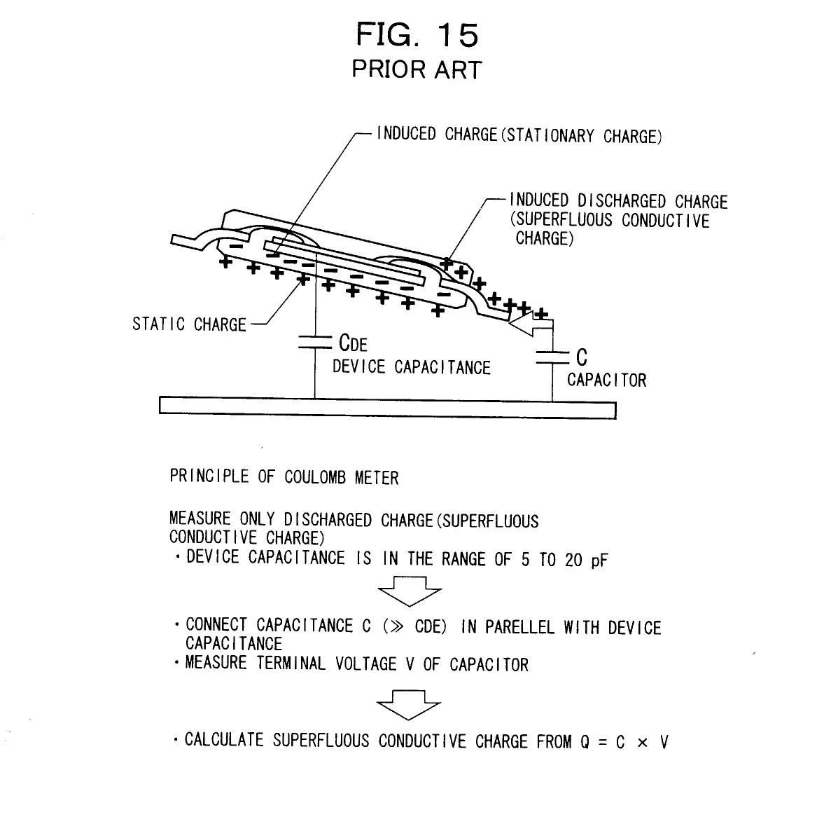

FIG. 12 shows a seventh example of the present invention. In FIG. 12, an example of application to a wafer-handling arm is shown.

As a matter of course, the present invention can be applied to a conveyance apparatus and a process apparatus that comes in direct contact with a part that is sensitive to and easily destroyed by static electricity discharge, such as an electronic part. For example, the present invention can be applied to jigs and tools that handle a GMR head or the like of a hard disk drive, and the present invention can also be applied to jigs and tools that handle a semiconductor wafer carrier.

As shown in the third embodiment, the fourth to seventh embodiment can be used a low pass filter (LPF), a high pass filter (HPF) or a band pass filter (BPF) to reduce noises and obtain accurate data without an influence by noises.

Owing to the above-described configuration, the present invention brings about the following effects.

(1) Even in the ionized environment, the electrification charge quantity can be measured with high precision.

(2) Even in the in-line state, the electrification charge quantity of an apparatus can be measured with high precision.

(3) It is suitable for measurement of the electrification quantity of semiconductor devices and hard disk apparatuses.

(4) Static electricity discharge can be detected. By attaching the apparatus to each part, the location thereof can be determined easily.

What is claimed is:

1. An electrification quantity measurement apparatus comprising:
a measurement subject placed in an ionizer environment;
a probe for coming in contact with said measurement subject;
a first resistor, a first terminal of which connects to said probe;
a capacitor connected between a second terminal of said first resistor and ground; and
offset current cancel means for canceling an offset current of said capacitor generated by an ionizer in order to measure an electrification quantity of said measurement subject.

2. The electrification quantity measurement apparatus according to claim 1, wherein said offset current cancel means comprising:
a voltage source;
a second resistor for applying an output voltage of said voltage source to a connection node between said first resistor and said capacitor, said second resistor being sufficiently higher in resistance than that of said first resistor; and
control means for controlling an output voltage of said voltage source in response to a terminal voltage of said capacitor.

3. The electrification quantity measurement apparatus according to claim 1, wherein said offset current cancel means comprising:
a current source; and
control means for controlling an output current of said current source in response to a terminal voltage of said capacitor.

4. The electrification quantity measurement apparatus according to claim 2, wherein said apparatus further comprising:
a third resistor connected between terminals of said capacitor so as to discharge charge within said capacitor; and
recording means for acquiring a discharge current that flows through said third resistor or a discharge voltage of said capacitor.

5. The electrification quantity measurement apparatus according to claim 2, wherein said apparatus further comprising:
a third resistor connected between terminals of said capacitor so as to discharge charge within said capacitor; and
measurement means for measuring a peak value of a discharge current that flows through said third resistor or a peak value of a discharge voltage of said capacitor.

6. The electrification quantity measurement apparatus according to claim 2, wherein said apparatus further comprising:
a third resistor connected between terminals of said capacitor so as to discharge charge within said capacitor; and
an integration circuit for integrating a discharge current that flows through said third resistor.

7. An electrification quantity measurement apparatus comprising:
a measurement subject;
a probe for coming in contact with said measurement subject a first resistor, a first terminal of which connects to said probe;
a capacitor connected between a second terminal of said first resistor and ground;
a second resistor connected between terminals of said capacitor so as to discharge charge within said capacitor; and
recording means for recording a change of discharge current that flows through said second resistor.

8. An electrification quantity measurement apparatus comprising:
a measurement subject;
a probe for coming in contact with said measurement subject;
a first resistor, a first terminal of which connects to said probe;
a capacitor connected between a second terminal of said first resistor and ground;
a second resistor connected between terminals of said capacitor so as to discharge charge within said capacitor; and
measurement means for measuring a peak value of a discharge current that flows through said second resistor.

9. An electrification quantity measurement apparatus comprising:
a measurement subject;
a probe for coming in contact with said measurement subject;
a first resistor, a first terminal of which connects to said probe;
a capacitor connected between a second terminal of said first resistor and ground;
a second resistor connected between terminals of said capacitor so as to discharge charge within said capacitor; and
an integration circuit for integrating a discharge current that flows through said second resistor.

10. An electrification quantity measurement apparatus comprising:
a measurement subject;
a resistor connected between said measurement subject and ground; and
recording means for recording a current waveform that flows through said resistor.

11. An electrification quantity measurement apparatus comprising:
a measurement subject;
a resistor connected between said measurement subject and ground; and
measurement means for measuring a peak value of a discharge current that flows through said resistor.

12. An electrification quantity measurement apparatus comprising:
a measurement subject;
a first resistor, a first terminal of which connects to said measurement subject;
a capacitor connected between a second terminal of said first resistor and ground;
a second resistor connected between terminals of said capacitor so as to discharge charge within said capacitor; and
recording means for recording a change of discharge current that flows through said second resistor.

13. An electrification quantity measurement apparatus comprising:
a measurement subject;
a first resistor, a first terminal of which connects to said measurement subject;
a capacitor connected between a second terminal of said first resistor and ground;
a second resistor connected between terminals of said capacitor so as to discharge charge within said capacitor; and
measurement means for measuring a peak value of a discharge current that flows through said second resistor.

14. An electrification quantity measurement apparatus comprising:
a measurement subject;
a first resistor, a first terminal of which connects to said measurement subject;
a capacitor connected between a second terminal of said first resistor and ground;
a second resistor connected between terminals of said capacitor so as to discharge charge within said capacitor; and
an integration circuit for integrating a discharge current that flows through said second resistor.

15. The electrification quantity measurement apparatus according to claim 1, wherein said measurement subject is a semiconductor fabrication apparatus such as a stage, a shuttle, a wafer conveyance arm, and an adsorption arm of a handler.

16. A static electricity discharge detection apparatus comprising:
a tray and/or shuttle for conveying a part;
a resistor connected between said tray and/or shuttle and frame ground; and
recording means for recording a waveform of a discharge current that flows through said resistor.

17. A static electricity discharge detection apparatus comprising:
a tray and/or shuttle for conveying a part;
a resistor connected between said tray and/or shuttle and frame ground; and
measurement means for measuring a peak value of a discharge current that flows through said resistor and time taken until said peak is reached.

18. An electrification quantity measurement method using an apparatus comprising a probe for coming in contact with a measurement subject, a first resistor, a first terminal of which connecting to said probe, and a capacitor connected between a second terminal of said first resistor and ground, said method comprising the steps of:
discharging charge within said capacitor by using a second resistor;
deriving a waveform of a discharge current that flows through said second resistor; and
measuring an electrification charge quantity of said measurement subject by integrating said waveform of said discharge current.

19. An electrification quantity measurement method using an apparatus comprising a probe for coming in contact with a measurement subject, a first resistor, a first terminal of which connecting to said probe, and a capacitor connected between a second terminal of said first resistor and ground, said method comprising the steps of:
discharging charge within said capacitor by using a second resistor; and
measuring an electrification charge quantity of said measurement subject based on a peak voltage of said second resistor.

20. An electrification quantity measurement method using an apparatus comprising a probe for coming in contact with a measurement subject, a first resistor, a first terminal of which connecting to said probe, and a capacitor connected between a second terminal of said first resistor and ground, said method comprising the steps of:
discharging charge within said capacitor by using a second resistor; and
measuring an electrification charge quantity of said measurement subject by integrating a discharge current that flows through said second resistor.

21. An electrification quantity measurement method comprising the steps of:
connecting a resistor between a measurement subject and ground; and
measuring an electrification charge quantity of the measurement subject by recording a waveform of a current that flows through said resistor.

22. An electrification quantity measurement method using an apparatus comprising a first resistor, a first terminal of which connects to a measurement subject, a capacitor connected between a second terminal of said first resistor and ground, said method comprising the steps of:
discharging charge within said capacitor by using a second resistor;
deriving a waveform of a discharge current that flows through said second resistor; and
measuring an electrification charge quantity of said measurement subject by integrating a waveform of said discharge current.

23. An electrification quantity measurement method using an apparatus comprising a first resistor, a first terminal of which connects to a measurement subject, and a capacitor connected between a second terminal of said first resistor and ground, said method comprising the steps of:
discharging charge within said capacitor by using a second resistor; and
measuring an electrification charge quantity of said measurement subject by integrating a discharge current that flows through said second resistor.

24. A static electricity discharge detection method comprising the steps of:
connecting a resistor between a tray and/or shuttle provided in a conveyance apparatus for conveying parts and frame ground; and
detecting generation of static electricity discharge by monitoring a waveform of a discharge current that flows through said resistor.
